(19) United States
(12) Patent Application Publication
(10) Pub. No.: US 2025/0338580 A1
(43) Pub. Date: Oct. 30, 2025

(54) SEMICONDUCTOR DEVICES WITH SUPERLATTICE LAYERS IN SOURCE/DRAIN REGIONS AND MANUFACTURING METHODS THEREOF

(71) Applicant: Taiwan Semiconductor Manufacturing Company, Ltd., Hsin-Chu (TW)

(72) Inventors: Min Cao, Hsinchu (TW); Jin Cai, Hsinchu City (TW); Hou-Yu Chen, Hsinchu County (TW)

(21) Appl. No.: 18/830,959

(22) Filed: Sep. 11, 2024

Related U.S. Application Data
(60) Provisional application No. 63/638,167, filed on Apr. 24, 2024.

(51) Int. Cl. H01L 29/10; H01L 21/02; H01L 29/06; H01L 29/423; H01L 29/66; H01L 29/775; H01L 29/786

(52) U.S. Cl. CPC H10D 62/371; H01L 21/02373; H01L 21/02634; H10D 62/116; H10D 30/014; H10D 30/43; H10D 30/6735; H10D 30/6757; H10D 62/121

(57) ABSTRACT

The present disclosure provides a semiconductor device and a method of forming the same. A method according one embodiment of the present disclosure includes forming a first stack over a substrate and a second stack over the first stack. The first stack includes semiconductor layers interleaved by dielectric layers. The second stack includes channel layers interleaved by sacrificial layers. The method also includes patterning the second stack to form a fin-shape structure, recessing a portion of the fin-shape structure to form a recess exposing a top surface of the first stack, epitaxially growing an epitaxial feature directly from the top surface of the first stack, removing the sacrificial layers to release the channel layers, and forming a gate structure wrapping around each of the channel layers.

### PRIORITY DATA

This application claims priority to U.S. Provisional Patent Application No. 63/638,167, filed on Apr. 24, 2024, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can wrap around a channel region to provide access to the channel region on four sides. As multi-gate devices continue to scale, challenges have arisen. For example, to improve performance of multi-gate devices, efforts are invested to develop epitaxial features in source/drain regions that strain channels with low substrate current leakage. While conventional epitaxial features in source/drain regions are generally adequate to their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIGS. 2, 3, 4, 5, 6, 7, 8, 9, 10, 11, 12, 13, 14, 15, 16, 17, 18, 19, 20, 21, 22, 23, 24, 25, 26, 27, 28, 29, 30, and 31 illustrate fragmentary cross-sectional views of a workpiece during a fabrication process according to the method of FIG. 1, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The present disclosure is generally related to multi-gate transistors and fabrication methods, and more particularly to multilayer structures in source/drain regions of multi-gate transistors.

A channel region of a multi-gate transistor extends between and are coupled to two source/drain features. In a FinFET transistor, the channel region may be disposed in a fin protruding from a substrate; in a GAA transistor, the channel region may be disposed in a stack of nanostructures, also referred to as channel members, suspended above a substrate. Source/drain features of a multi-gate transistor are expected to introduce strain on the channel region with low substrate current leakage. During the formation of a multi-gate transistor, inserting a dielectric film under the source/drain features may help isolating the source/drain features from the substrate and thus suppress leakage current into the substrate. Although such a dielectric film is helpful to boost AC performance, it may deteriorate DC performance in p-type FETs with an increased resistance. The deterioration of DC performance in p-type FETs may be due to a loss of compressive strain when the epitaxial growth of the source/drain features is excluded from the substrate as a result of the substrate being isolated by the dielectric film.

Embodiments of the present disclosure provide a semiconductor device where a superlattice is formed in source/drain regions prior to the epitaxial growth of the source/drain features. The superlattice includes superlattice layers arranged in a sandwich structure, such as semiconductor layer(s) and non-semiconductor (and non-metal) monolayer(s) being allocated in an alternating pattern. The non-semiconductor monolayer(s) is non-conductive and thus provides isolation between the source/drain features and the substrate. Meanwhile, the superlattice layers each are sufficiently thin, such that the alternating layers preserves the crystalline structure extending from the substrate (i.e., the same crystalline orientation as the substrate), which allows the source/drain features to epitaxially grow from the bottom of the source/drain regions besides from sidewalls of the channel regions. Further, a base epitaxial layer may optionally be formed between the substrate and the superlattice layers or between the superlattice layers and the source/drain features. The base epitaxial layer may be undoped to increase its resistance, which further improves the suppression of leakage current from the source/drain features into the substrate. The superlattice layers may be applied in the source/drain regions of p-type FETs (e.g., with a dielectric film still applied in the source/drain regions of n-type FETs as a replacement of the superlattice layers) or in the source/drain regions of both p-type and n-type FETs.

For the purposes of simplicity, the present disclosure uses GAA transistors as an example. The channel region of a GAA transistor may be disposed in nanowire channel members, bar-shaped channel members, nanosheet channel members, nanostructure channel members, column-shaped channel members, post-shaped channel members, and/or other suitable channel configurations. Despite of the shapes of the channel region, those of ordinary skill in the art should appreciate that they may readily use the present disclosure as a basis for designing or modifying other multi-gate devices (such as FinFETs) for carrying out the same purposes and/or achieving the same advantages of the embodiments introduced herein.

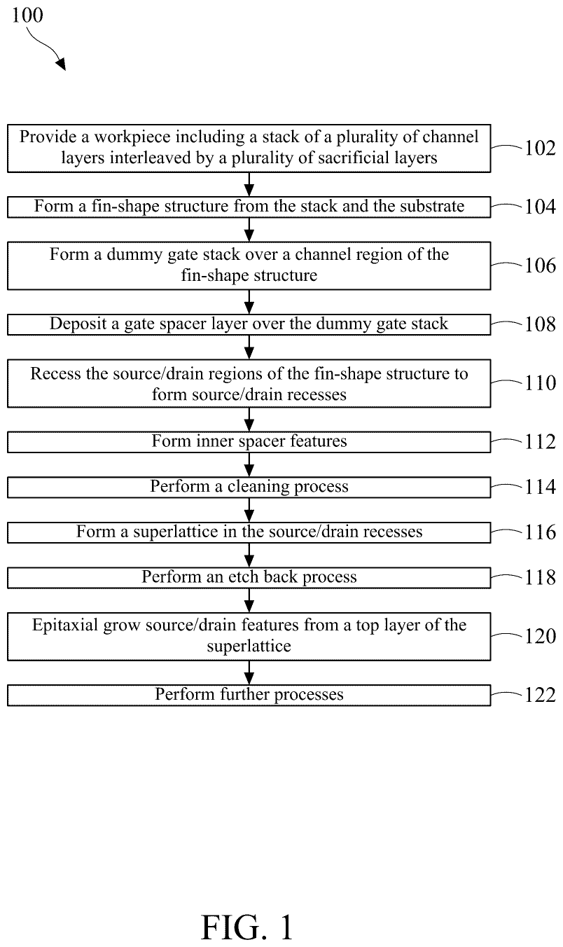

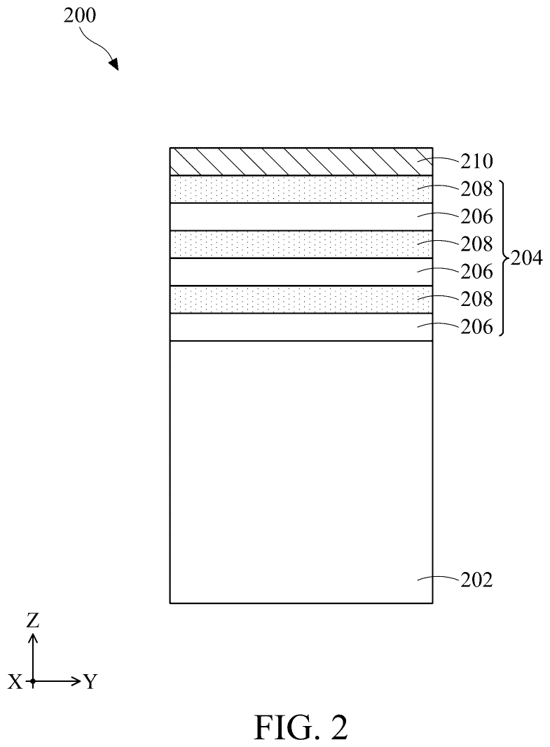

The various aspects of the present disclosure will now be described in more detail with reference to the figures. In that regard, FIG. 1 is a flowchart illustrating a method 100 of forming a semiconductor device from a workpiece according to embodiments of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIGS. 2-31, which are fragmentary cross-sectional views of workpiece 200 at different stages of fabrication according to embodiments of the method 100 in FIG. 1. Because the workpiece 200 will be fabricated into a semiconductor device, the workpiece 200 may be referred to herein as a semiconductor device 200 as the context requires. For avoidance of any doubt, the X, Y and Z directions in FIGS. 2-31 are perpendicular to one another. Throughout the present disclosure, like reference numerals denote like features, unless otherwise excepted.

Referring to FIGS. 1 and 2, method 100 includes a block 102 where a stack 204 of alternating semiconductor layers is formed over the workpiece 200. As shown in FIG. 2, the workpiece 200 includes a substrate 202. In an embodiment, the substrate 202 is a bulk substrate comprising a single crystalline semiconductor material, such as silicon (Si), or a compound semiconductor material such as silicon germanium (SiGe). The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P) or arsenide (As). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 includes sacrificial layers 206 of a first semiconductor composition interleaved by channel layers 208 of a second semiconductor composition. The first and second semiconductor composition may be different. In some embodiments, the sacrificial layers 206 include silicon germanium (SiGe) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 1 and 20.

In some embodiments, all sacrificial layers 206 may have a substantially uniform first thickness between about 3 nm and about 10 nm and all of the channel layers 208 may have a substantially uniform second thickness between about 3 nm and about 15 nm. The first thickness and the second thickness may be the same or different. As described in more detail below, the channel layers 208 or parts thereof may serve as channel member(s) for a subsequently-formed multi-gate device and the thickness of each of the channel layers 208 is chosen based on device performance considerations. The sacrificial layers 206 in channel regions(s) may eventually be removed and serve to define a vertical distance between adjacent channel region(s) for a subsequently-formed multi-gate device and the thickness of each of the sacrificial layers 206 is chosen based on device performance considerations.

The layers in the stack 204 may be deposited using a molecular beam epitaxy (MBE) process, a vapor phase deposition (VPE) process, and/or other suitable epitaxial growth processes. Therefore, the stack 204 is also referred to as the epitaxial stack 204. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 cm⁻³ to about 1×10¹⁷ cm⁻³), where for example, no intentional doping is performed during the epitaxial growth processes for the stack 204. In some implementations, the top surface of the substrate 202 is in a (100) crystalline plane, and accordingly each layer of the stack 204 has a (100) top surface. In some alternative implementations, the top surface of the substrate is in a (110) crystalline plane, and accordingly each layer of the stack 204 has a (110) top surface.

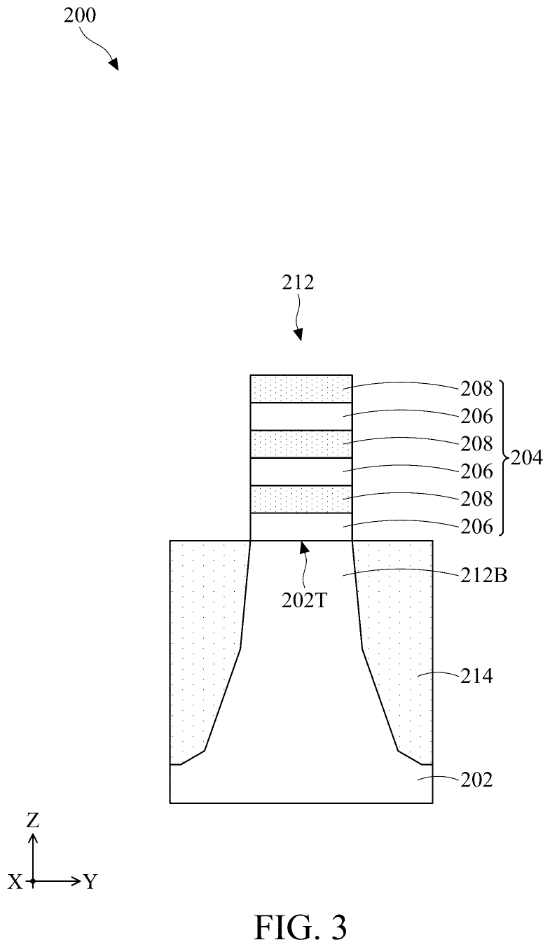

Referring to FIGS. 1, 2, and 3, method 100 includes a block 104 where a fin-shape structure 212 is formed from patterning the stack 204 and the substrate 202. To pattern the stack 204, a hard mask layer 210 (shown in FIG. 2) may be deposited over the stack 204 to form an etch mask. The hard mask layer 210 may be a single layer or a multi-layer. For example, the hard mask layer 210 may include a pad oxide layer and a pad nitride layer over the pad oxide layer. The fin-shape structure 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 3, the etch process at block 104 forms trenches extending through the stack 204 and a portion of the substrate 202. The trenches define the fin-shape structures 212. In some implementations, double-patterning or multi-patterning processes may be used to define fin-shape structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shape structure 212 by etching the stack 204 and a top portion of the substrate 202. The patterned top portion of the substrate 202 is also denoted as a fin-shape base 212B. A horizontal plane comprising an interface between the stack 204 and the fin-shape base 212B is denoted as the plane 202T, which marks a position of the bottom surface of the stack 204 and/or the top surface of the fin-shape base 212B. The fin-shape base 212B may still be considered as a top part of the substrate 202 as the context requires. Therefore, the plane 202T may also be considered as marking a position of the top surface of the substrate 202. As shown in FIG. 3, the fin-shape structure 212, which includes the patterned stack 204 and the fin-shape base 212B, extends vertically along the Z direction and lengthwise along the X direction. In some instances, the fin-shape structure 212 measures between about 6 nm and about 80 nm wide along the Y direction, and a distance between opposing sidewalls of two adjacent fin-shape structures 212 measures between about 6 nm and about 115 nm along the Y direction.

An isolation feature 214 is formed adjacent the fin-shape structure 212. In some embodiments, the isolation feature 214 may be formed in the trenches to isolate the fin-shape structures 212 from a neighboring active region. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214. The fin-shape structure 212 rises above the STI feature 214 after the recessing. The recessed top surface of the STI feature 214 may be leveled with the plane 202T or below the plane 202T.

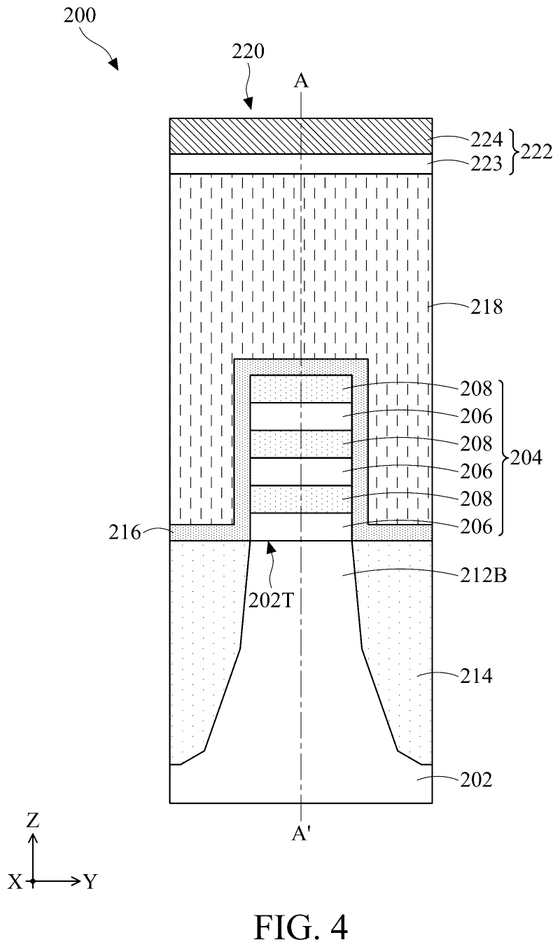

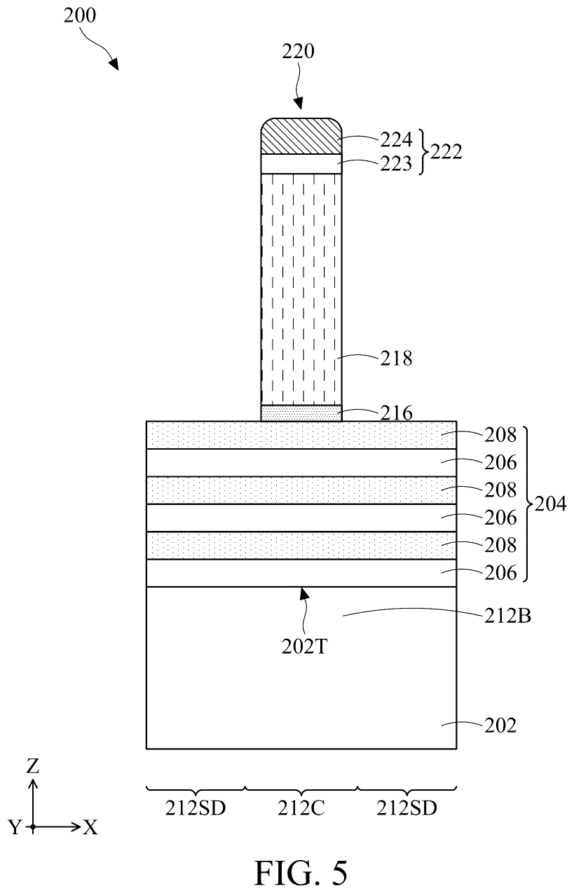

Referring to FIGS. 1, 4, and 5, method 100 includes a block 106 where a dummy gate stack 220 is formed over a channel region 212C of the fin-shape structure 212. FIG. 5 is a cross-sectional view cut through A-A′ line in FIG. 4. In some embodiments, a gate replacement process (or gate-last process) is adopted where the dummy gate stack 220 (shown in FIGS. 4 and 5) serves as a placeholder to undergo various processes and is to be removed and replaced by the functional gate structure. Other processes and configuration are possible. In some embodiments illustrated in FIG. 5, the dummy gate stack 220 is formed over the fin-shape structure 212, and the fin-shape structure 212 may be divided into channel regions 212C underlying the dummy gate stacks 220 and source/drain regions 212SD that do not underlie the dummy gate stacks 220. The channel regions 212C are adjacent the source/drain regions 212SD. As shown in FIG. 5, the channel region 212C is disposed between two source/drain regions 212SD along the X direction.

The formation of the dummy gate stack 220 may include deposition of layers in the dummy gate stack 220 and patterning of these layers. Referring to FIG. 4, a dummy dielectric layer 216, a dummy electrode layer 218, and a gate-top hard mask layer 222 may be blanketly deposited over the workpiece 200. In some embodiments, the dummy dielectric layer 216 may be formed on the fin-shape structure 212 using a chemical vapor deposition (CVD) process, an ALD process, an oxygen plasma oxidation process, or other suitable processes. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 5. For example, the patterning process may include a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 5, no dummy gate stack 220 is disposed over the source/drain region 212SD of the fin-shape structure 212.

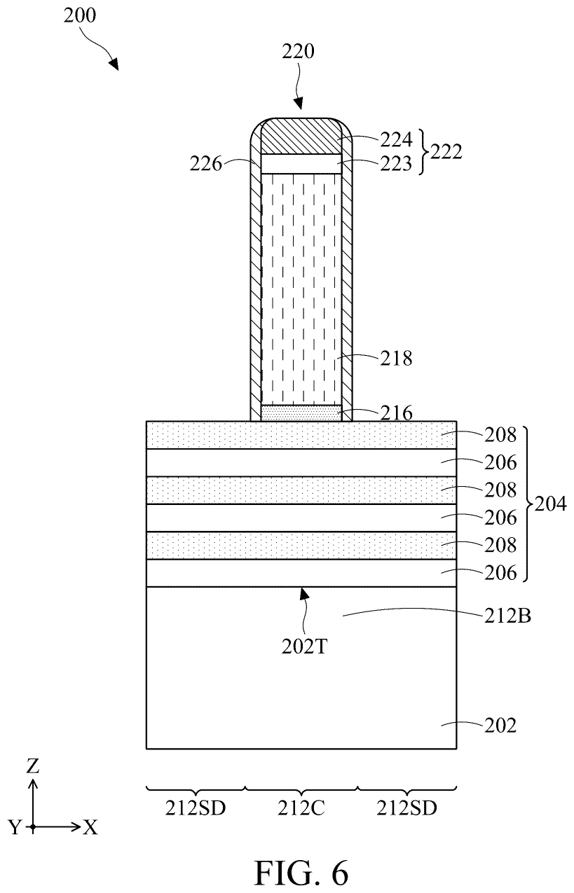

Referring to FIGS. 1 and 6, method 100 includes a block 108 where a gate spacer layer 226 is deposited over the dummy gate stack 220. In some embodiments, the gate spacer layer 226 is deposited conformally over the workpiece 200, including over top surface and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process. In one embodiment, the gate spacer layer 226 includes a first layer and a second layer disposed over the first layer. The first layer may include silicon oxynitride and the second layer may include silicon nitride. In some instances, the gate spacer layer 226 measures between about 3 nm and about 8 nm thick along the X direction.

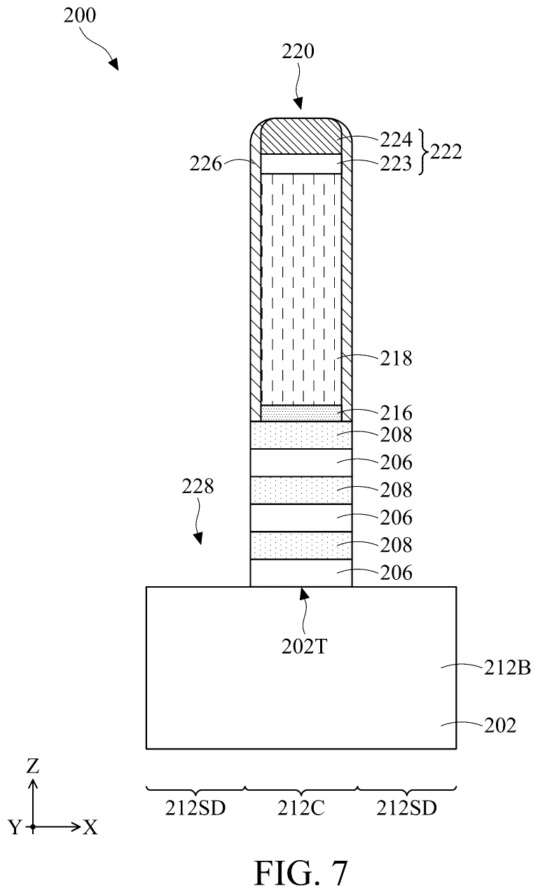

Referring to FIGS. 1 and 7, method 100 includes a block 110 where source/drain regions 212SD of the fin-shape structure 212 are recessed to form source/drain trenches (or referred to as source/drain recesses) 228. In some embodiments, the source/drain regions 212SD of the fin-shape structure 212 that are not covered by the dummy gate stack 220 and the gate spacer layer 226 are etched by a dry etch or a suitable etching process to form the source/drain trenches 228. For example, the dry etch process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBR3), an iodine-containing gas, other suitable gases and/or plasmas, and/or combinations thereof. The source/drain regions 212SD of the fin-shape structure 212 are recessed to expose sidewalls of the sacrificial layers 206 and the channel layers 208. As shown in FIG. 7, the sacrificial layers 206 and channel layers 208 in the source/drain region 212SD are removed, exposing the substrate 202. In the illustrated embodiment, the bottom of the source/drain trenches 228 is level with the bottom surface of the stack 204 (the plane 202T). In some implementations, the source/drain trenches 228 extend below the stack 204 into the substrate 202 (below the plane 202T). A width of the source/drain trench 228 (e.g., as measured between opposing sidewalls of the gate spacer layer 226 on adjacent dummy gate stacks 220 along the X direction) may range from about 9 nm to about 32 nm.

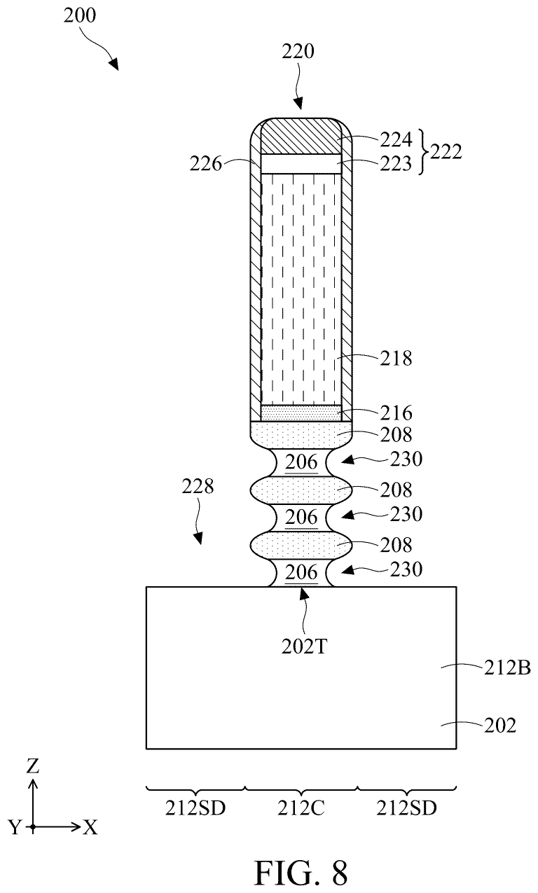

Referring to FIGS. 1, 8, 9, and 10, method 100 includes a block 112 where inner spacer features 234 are formed. Operation at block 112 may include selective and partial removal of the sacrificial layers 206 to form inner spacer recesses 230, deposition of inner spacer material 232 over the workpiece 200, and etch back the inner spacer material 232 to form inner spacer features 234 in the inner spacer recesses 230. The sacrificial layers 206 exposed in the source/drain trenches 228 (shown in FIG. 8) are selectively and partially recessed to form inner spacer recesses 230 while the gate spacer layer 226, the exposed portion of the substrate 202, and the channel layers 208 are substantially unetched. In an embodiment where the channel layers 208 consist essentially of silicon (Si) and sacrificial layers 206 consist essentially of silicon germanium (SiGe), the selective recess of the sacrificial layers 206 may be performed using a selective wet etch process or a selective dry etch process. The selective and partial recess of the sacrificial layers 206 may include a SiGe oxidation process followed by a SiGe oxide removal. In that embodiment, the SiGe oxidation process may include use of ozone. In some other embodiments, the selective dry etching process may include use of one or more fluorine-based etchants, such as fluorine gas or hydrofluorocarbons. The selective wet etching process may include an APM etch (e.g., ammonia hydroxide-hydrogen peroxide-water mixture).

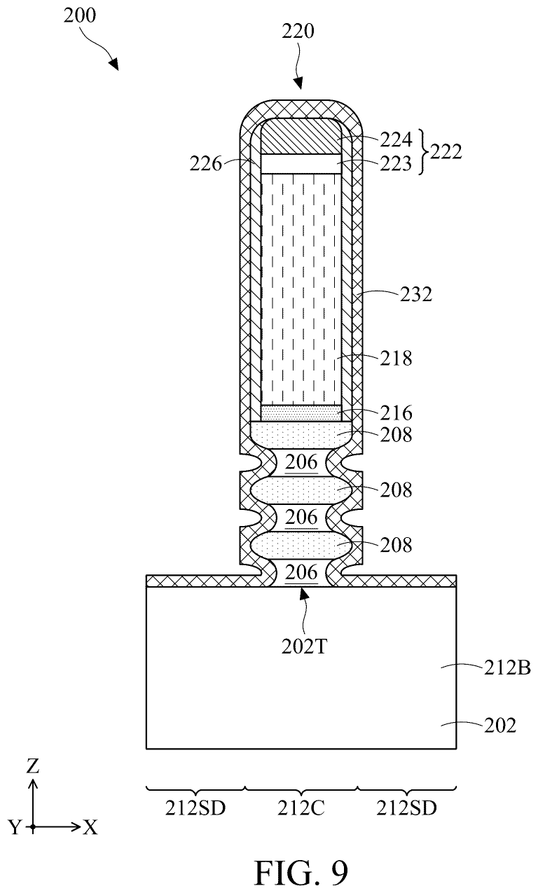

After the inner spacer recesses 230 are formed, the inner spacer material 232 is deposited over the workpiece 200, including over the inner spacer recesses 230, as shown in FIG. 9. The inner spacer material 232 may include metal oxides, silicon oxide, silicon oxycarbonitride, silicon nitride, silicon oxynitride, carbon-rich silicon carbonitride, or a low-k dielectric material. The metal oxides may include aluminum oxide, zirconium oxide, tantalum oxide, yttrium oxide, titanium oxide, lanthanum oxide, or other suitable metal oxide. While not explicitly shown, the inner spacer material 232 may be a single layer or a multilayer. In some implementations, the inner spacer material 232 may be deposited using CVD, PECVD, SACVD, ALD or other suitable methods. The inner spacer material 232 is deposited into the inner spacer recesses 230 as well as over the sidewalls of the channel layers 208 exposed in the source/drain trenches 228.

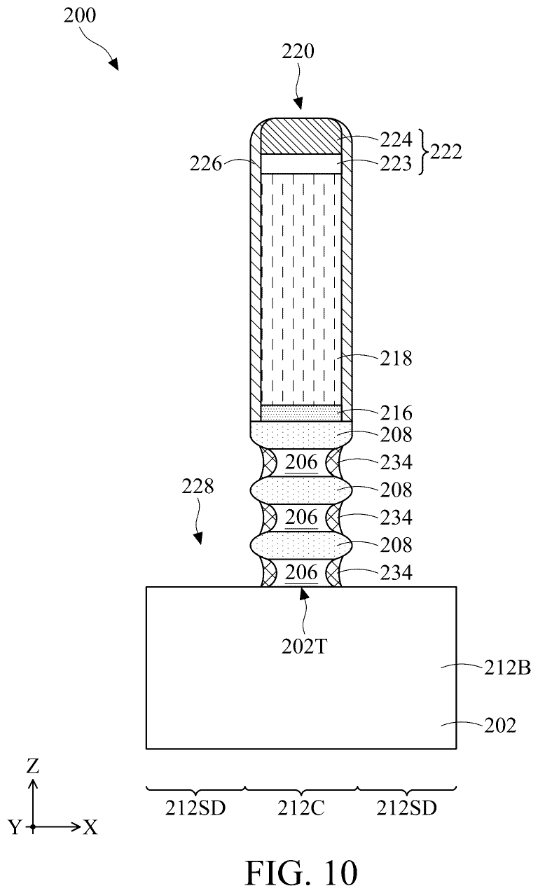

The deposited inner spacer material 232 is then etched back to remove the inner spacer material 232 from the sidewalls of the channel layers 208 to form the inner spacer features 234 in the inner spacer recesses 230, as shown in FIG. 10. At block 112, the inner spacer material 232 may also be removed from the top surfaces and/or sidewalls of the gate-top hard mask layer 222 and the gate spacer layer 226. In some implementations, the etch back operations performed at block 112 may include use of hydrogen fluoride (HF), fluorine gas (F₂), hydrogen (H₂), ammonia (NH₃), nitrogen trifluoride (NF₃), or other fluorine-based etchants. As shown in FIG. 10, each of the inner spacer features 234 is in direct contact with the recessed sacrificial layers 206 and is disposed between two neighboring channel layers 208. In some instances, each of the inner spacer features 234 measures between about 3 nm and about 5 nm thick along the X direction. In the depicted embodiment, each of the inner spacer features 234 has a concave sidewall surface facing the respective source/drain trench 228 (i.e., bending inward towards the respective sacrificial layer 206). Alternatively, the sidewall surface may be flat (e.g., substantially vertical) or convex (i.e., bending outward towards the respective source/drain trench 228). As shown in FIG. 10, while the selective etch process and etch back process at block 112 are selective to the sacrificial layers 206 and the inner spacer material 232, the channel layers 208 are moderately etched and have rounded ends.

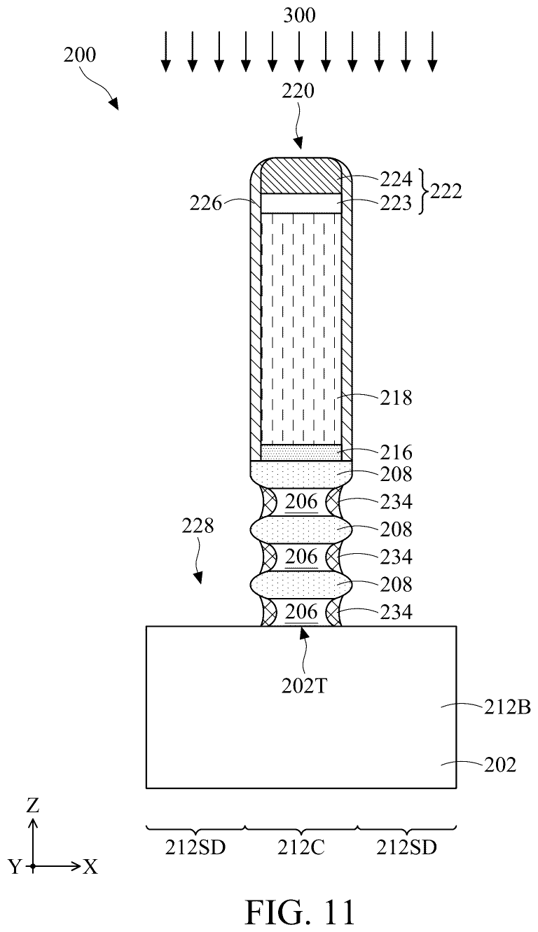

Referring to FIGS. 1 and 11, method 100 includes a block 114 where a cleaning process 300 is performed. The cleaning process 300 may include a dry clean, a wet clean, or a combination thereof. In some examples, the wet clean may include use of a mixture of deionized (DI) water, ammonium hydroxide, and hydrogen peroxide, a mixture of DI water, hydrochloric acid, and hydrogen peroxide, a sulfuric peroxide mixture, and/or hydrofluoric acid for oxide removal. The dry clean process may include helium (He) and hydrogen (H₂) treatment at a temperature between about 250° C. and about 550° C. and under a pressure between about 75 mTorr and about 155 mTorr. The hydrogen treatment may convert silicon on the surface to silane (SiH₄), which may be pumped out for removal. In some implementations, the cleaning process is configured to selectively remove or trim a portion of the channel layers without substantially removing the inner spacer features 234. The cleaning process 300 may remove surface oxide and debris in order to ensure a clean semiconductor surface, which facilitates growth of a superlattice in the bottom of the source/drain trenches 228 in subsequent operations.

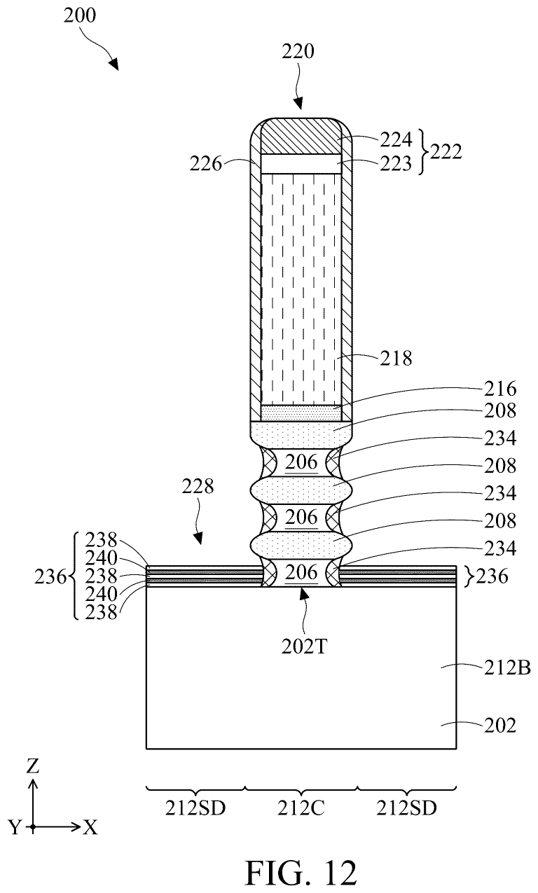

Referring to FIGS. 1 and 12, method 100 includes a block 116 where a superlattice 236 is formed in the bottom of the source/drain trenches 228 and over the exposed portion of the substrate 202. A superlattice is a periodic structure consisting of alternating layers of different material compositions. These layers are typically only a few nanometers thick or even sub-nanometers thick, creating a repeating pattern at the nanoscale, also referred to as superlattice layers. In the illustrated embodiment, the superlattice 236 include a sandwich structure with one or more semiconductor layers 238 and one or more non-semiconductor (and non-metal) layers 240 allocated in an alternating pattern.

Each of the semiconductor layers 238 may comprise a base semiconductor selected from semiconductor materials such as silicon, silicon germanium, gallium arsenide, and/or other group III, IV, and V elements. In one example, the semiconductor layers 238 include silicon (Si). In some embodiments, a thickness of each semiconductor layer 238 is between about 1 nm and about 2 nm. This thickness range is not trivial or arbitrary. This thickness range allows the semiconductor layer 238 to preserve a continuous crystalline structure. A thickness above this range may introduce amorphous state into the semiconductor layers 238. A thickness under this range may be difficult for the manufacturing process to control a continuous film. Further, the thickness of each semiconductor layer 238 may be uniform or non-uniform. For example, the overlying and underlying semiconductor layers 238 sandwiching the non-semiconductor layer 240 may have different thicknesses, such as the overlying semiconductor layer 238 being thicker than the underlying semiconductor layer 238 or vice versa.

Between the overlying and underlying semiconductor layers 238, there may be a non-semiconductor (and non-metal) monolayer or a plurality of bonded non-semiconductor (and non-metal) monolayers, which in combination form a non-semiconductor layer 240. The non-semiconductor layer 240 is a non-conductive layer providing electrical isolation, also referred to as non-conductive layer 240 or isolation layer 240. In some embodiments, the non-semiconductor layer 240 may be a dielectric layer that includes oxygen, nitrogen, fluorine, carbon-oxygen, or the like. In furtherance of some embodiments, the non-semiconductor layers 240 include silicon dioxide (SiO₂) or oxygen doped silicon (SiOₓ). In some alternative embodiments, the non-semiconductor layers 240 includes silicon nitride (Si₃N₄) or nitrogen doped silicon (SiN_{y}). Each of the non-semiconductor layers 240 is tightly bonded to the overlying and underlying semiconductor layers 238 to form a superlattice structure (e.g., a Si/SiO₂ superlattice or a Si/Si₃N₄ lattice). In one example, the superlattice 236 is a Si/SiO₂ superlattice with an overall ratio of Si:O between about 3:2 and about 1:2. In another example, the superlattice 236 is a Si/Si₃N₄ superlattice with an overall ratio of Si:N between about 3:2 and about 3:4. In one embodiment, only one monolayer as the non-semiconductor layer 240 exists between the overlying and the underlying semiconductor layers 238. However, there can be two, three, or more than three monolayers bonded together as one non-semiconductor layer 240. This is partially due to the difficulty in the control of the formation of the monolayers. In some embodiments, a thickness of each non-semiconductor layer 240 is between about 0.2 nm and about 0.5 nm. This thickness range is not trivial or arbitrary. This thickness range allows the non-semiconductor layer 240 to preserve a continuous crystalline structure. A thickness above this range may introduce amorphous state into the non-semiconductor layers 240. A thickness under this range may be difficult for the manufacturing process to control a continuous film. Further, the thickness of each non-semiconductor layer 240 may be uniform or non-uniform.

In the illustrated embodiment, where the top portion of the substrate 202 includes a crystalline semiconductor material, an epitaxial growth may be performed to grow superlattice layers 238 and 240 on the substrate 202, such as an atomic layer deposition (ALD) process or other suitable methods. For example, the semiconductor layers 238 may be formed in an ALD process, and the non-semiconductor layers 240 may be formed in an ALD process or in an oxidation process by passivation a top surface layer of the semiconductor layer 238. The superlattice layers 238 and 240 are un-doped. It is noted that three (3) layers of the semiconductor layers 238 and two (2) layers of the non-semiconductor layers 240 are alternately arranged as illustrated in FIG. 12, which is for illustrative purposes only and not intended to be limiting beyond what is specifically recited in the claims. The number of the non-semiconductor layers 240 depends on the isolation needed for device performance, such as two (2) to seven (7) layers. Generally, a larger number of the non-semiconductor layers 240, a larger isolation is provided between the subsequently-formed epitaxial features and the substrate. In some embodiments, a thickness of the superlattice 236 is between about 2 nm and about 10 nm. This thickness range is not trivial or arbitrary. A thickness under this range may not have a sufficient number of the non-semiconductor layers 240 thus an insufficient isolation. A thickness above this range may be too thick such that the superlattice 236 may partially cover sidewalls of the bottommost channel layer 208 and reduce current drive capability of the transistor. Further, it is noted that the topmost and bottommost superlattice layers are both the semiconductor layers 238 as illustrated in FIG. 12, which is for illustrative purposes only and not intended to be limiting beyond what is specifically recited in the claims. In various embodiment, the topmost superlattice layer and the bottommost superlattice layer each can independently be the semiconductor layer 238 or the non-semiconductor layer 240.

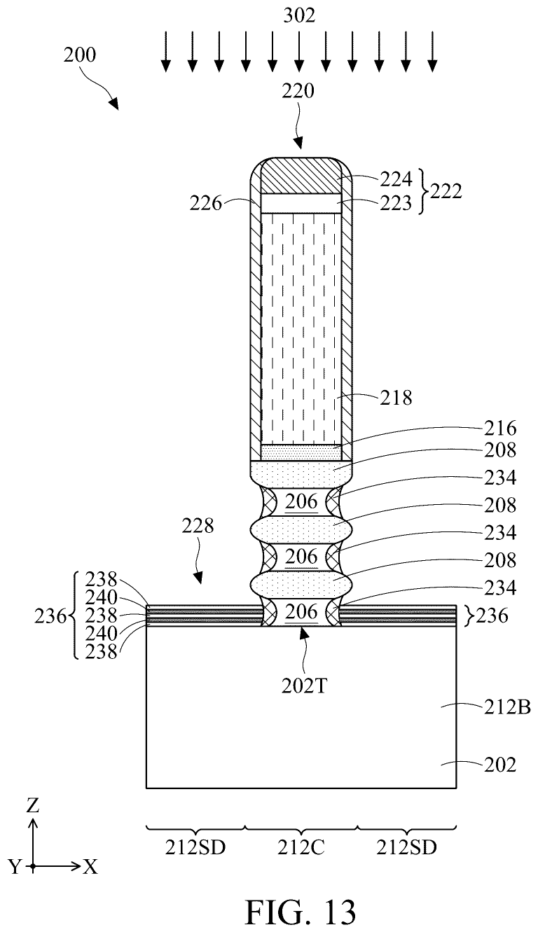

Referring to FIGS. 1 and 13, method 100 includes a block 118 where an etch back process 302 is performed to clean up sidewalls of the source/drain trenches 228 as the epitaxial growing of the superlattice 236 may also deposit materials of the superlattice layers on exposed semiconductor surfaces in the source/drain trenches 228 other than the top surface of the substrate 202, such as the sidewall of the channel layers 208. In some implementations, the etch back operations performed at block 118 may include use of hydrogen fluoride (HF), fluorine gas (F₂), hydrogen (H₂), ammonia (NH₃), nitrogen trifluoride (NF₃), or other fluorine-based etchants. The removal of the epitaxial residues on the sidewalls of the channel layers 208 may also recess (or thin down) the superlattice 236 in the bottom of the source/drain trenches 228. For example, the superlattice 236 may lose one or two layers of the semiconductor layers 238 and/or the non-semiconductor layers 240, but the remaining portion of the superlattice 236 still covers the top surface of the substrate 202 from being exposed in the source/drain trenches 228.

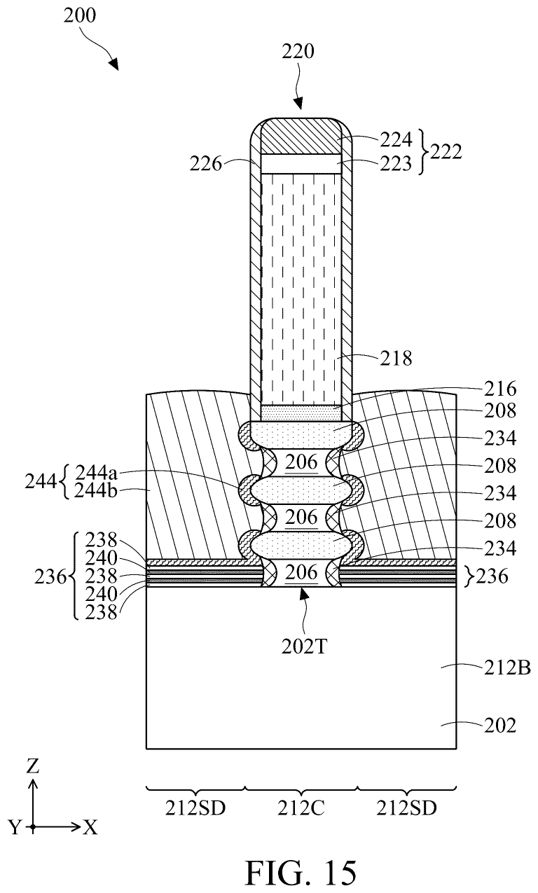

Referring to FIGS. 1, 14, and 15, method 100 includes a block 120 where source/drain features 244 are epitaxially grown from the exposed crystalline surfaces in the source/drain trenches 228, including from the sidewalls of the channel layers 208 and from the top surface of the superlattice 236. The superlattice 236 extends the crystalline structure from the top portion of the substrate 202, which allows the epitaxial growth of the source/drain features 244 to take place also from the bottom of the source/drain trenches 228. The source/drain features 244 may be p-type or n-type. When the source/drain feature 244 is p-type, the source/drain feature 244 may include silicon germanium (SiGe) and a p-type dopant, such as boron (B), boron difluoride (BF₂), or a combination thereof. When the source/drain feature 244 is n-type, the source/drain feature 244 may include silicon (Si) and an n-type dopant, such as phosphorus (P), arsenic (As), antimony (Sb), or a combination thereof. As further illustrated in FIG. 15, in some embodiments, the source/drain feature 244 may include multiple layers. For example, the source/drain feature 244 may include a lightly doped epitaxial layer 244a in contact with the rounded ends of channel layers 208 and covers the top surface of the superlattice 236, and a heavily doped epitaxial layer 244b in contact with the inner spacer features 234 and over the lightly doped epitaxial layer 244a. The lightly doped epitaxial layer 244a includes smaller dopant concentration and impurity concentration to reduce crystalline defects. The heavily doped epitaxial layer 244b accounts for a majority of the volume of the source/drain features 244 to reduce contact resistance. The source/drain features 244 may be formed using vapor-phase epitaxy (VPE), ultra-high vacuum CVD (UHV-CVD), or molecular beam epitaxy (MBE). Doping of the source/drain features 244 may be achieved with in-situ doping. For simplicity, the various sub-layers in the source/drain features 244, such as the epitaxial layers 244a and 244b, would not be separately illustrated in the following figures.

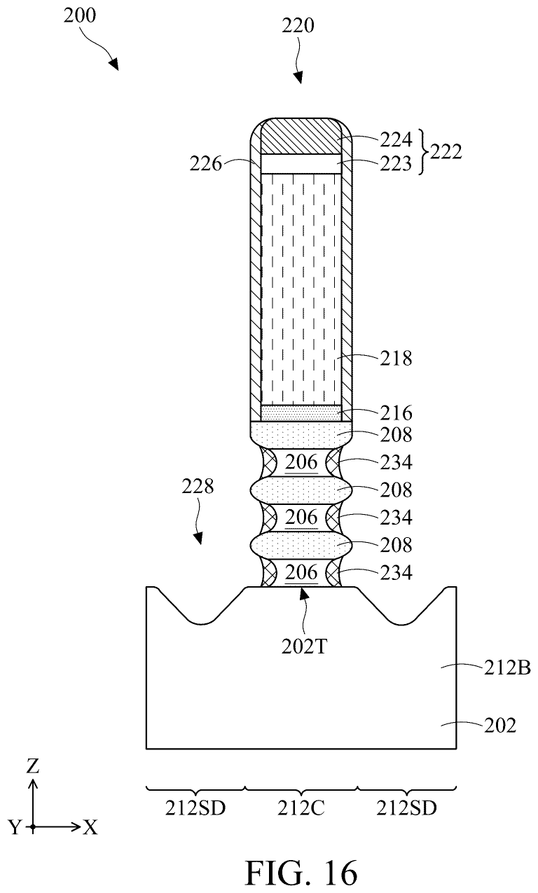

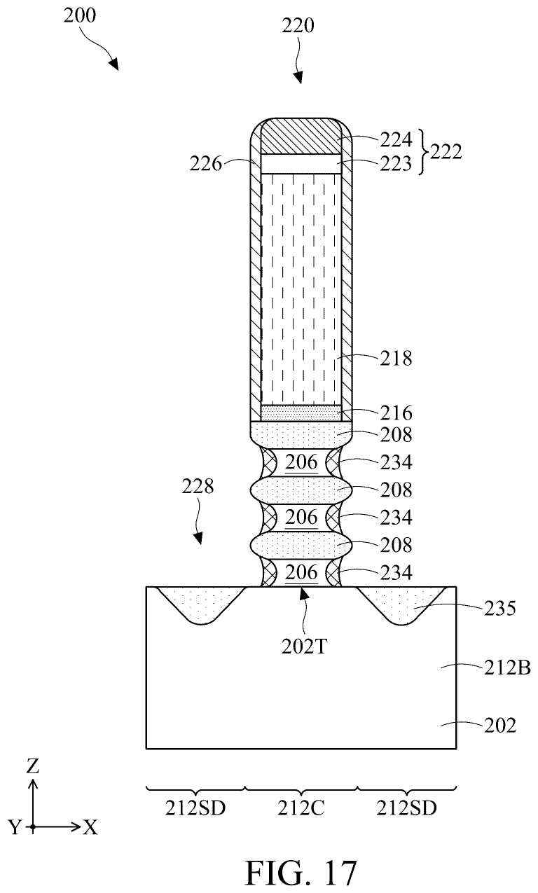

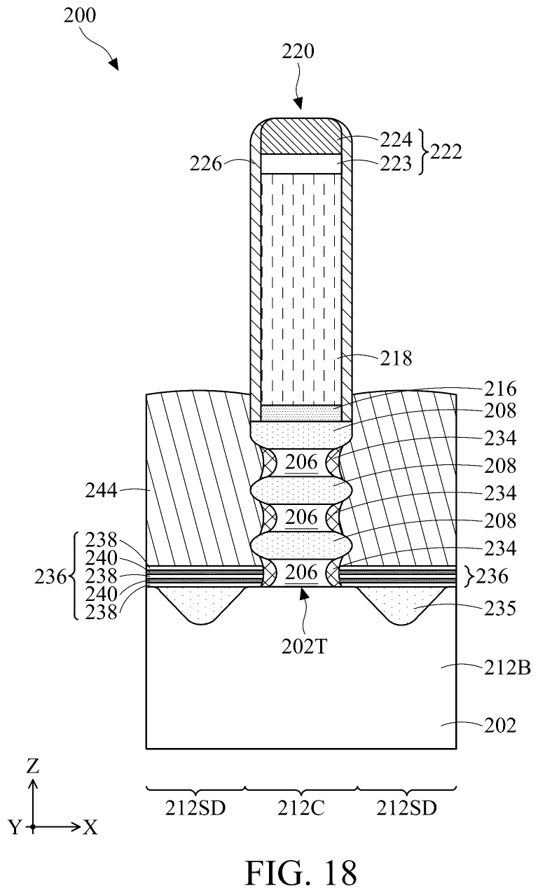

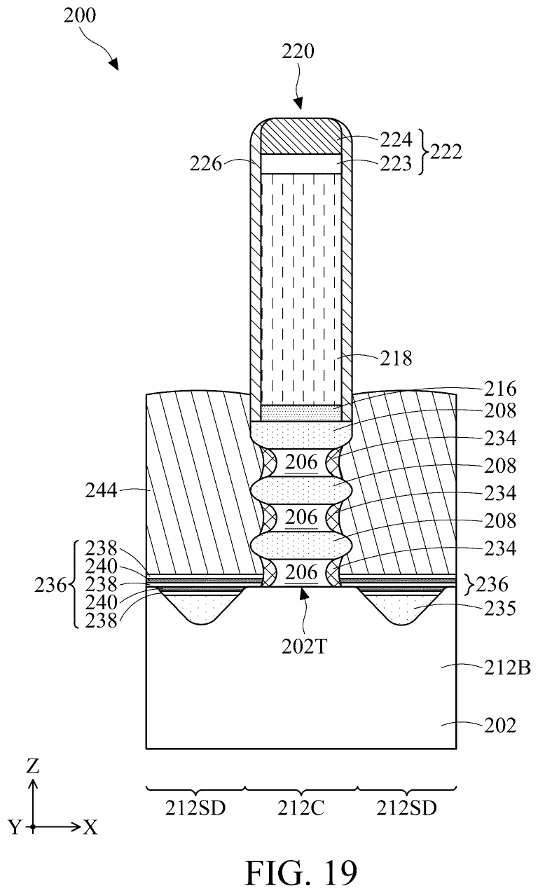

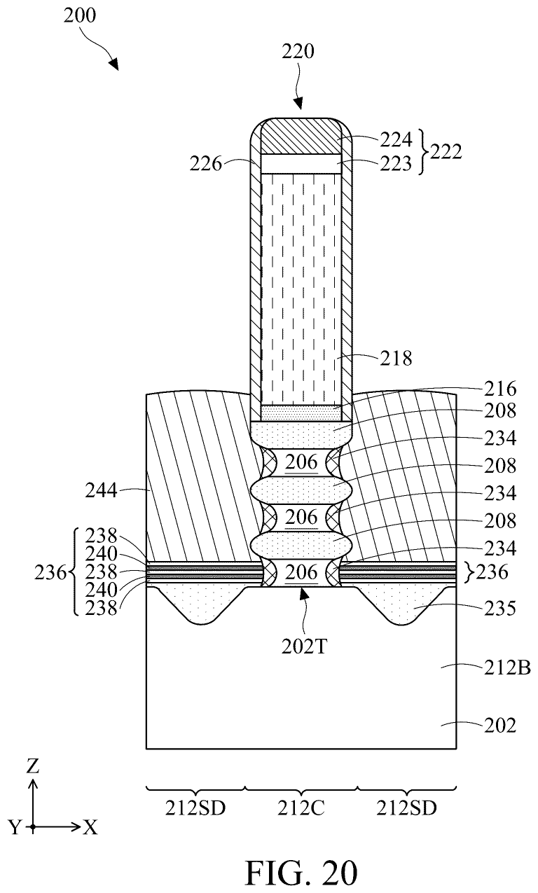

Referring to FIGS. 16-20, method 100 may optionally form a base epitaxial layer 235 prior to the forming of the superlattice 236. In an exemplary process, method 100 at block 110 may recess the source/drain trenches 228 further into the substrate 202 such as to a depth below the plane 202T, as shown in FIG. 16. Subsequently, after the formation of the inner spacer features 234 at block 112, a base epitaxial layer 235 is deposited in the bottom of the source/drain trenches 228, as shown in FIG. 17. In some embodiments, the base epitaxial layer 235 includes the same material as the substrate 202 and the channel layers 208, such as silicon (Si), except for a dopant condition (doping element and/or doping concentration). For example, the base epitaxial layer 235 is made of un-doped silicon, the substrate 202 is made of doped silicon, and the channel layers 208 are made of un-doped or doped silicon. In some embodiments, the base epitaxial layer 235 includes the same material as the sacrificial layers 206, such as silicon germanium (SiGe), with the germanium (Ge) content different from each other. In various embodiments, the base epitaxial layer 235 is dopant-free, where for example, no intentional doping is performed during the epitaxial growth process. The dopant-free base epitaxial layer 235 provides a high resistance path such that the leakage current into the substrate 202 is further suppressed. Suitable epitaxial processes for block 116 include vapor-phase epitaxy (VPE), molecular beam epitaxy (MBE), selective CVD, and/or other suitable processes. After the deposition of the base epitaxial layer 235, method 100 proceeds to blocks 114-120 in forming the superlattice 236 atop the base epitaxial layer 235 and the source/drain features 244 atop the superlattice 236, as shown in FIG. 18. In FIG. 18, the bottom surface of the superlattice 236 is level with the plane 202T and the top surface of the superlattice 236 intersects the sidewall of the bottommost inner spacer feature 234 (below the bottom surface of the bottommost channel layer 208). Alternatively, depending on the thickness of the base epitaxial layer 235, the bottom surface of the superlattice 236 may be below the plane 202T as shown in FIG. 19 or above the plane 202T as shown in FIG. 20. Further, depending on the flatness of the top surface of the base epitaxial layer 235, the bottom surface of the superlattice 236 may be flat or curvature (e.g., a convex shape bending downward).

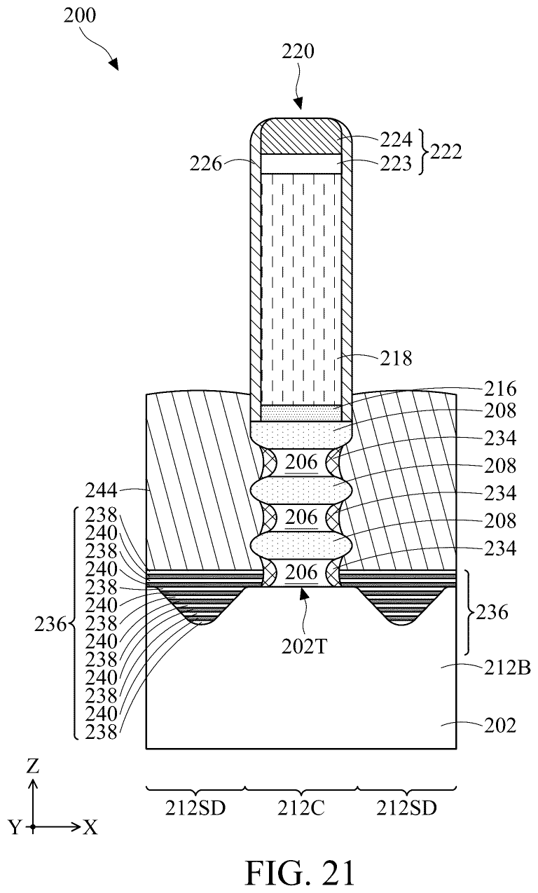

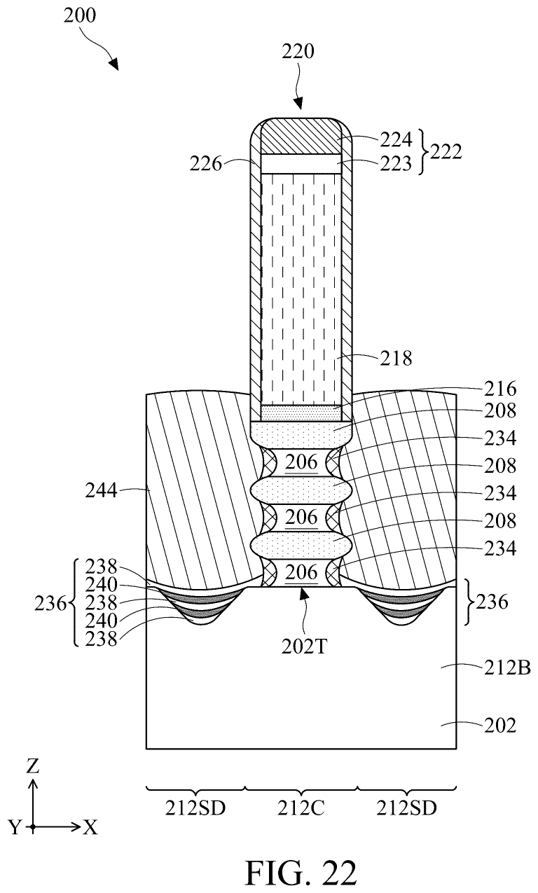

In some alternative embodiments, after the source/drain trenches 228 are extended further into the substrate 202 as shown in FIG. 16, method 100 may proceeds to blocks 114-120 without forming the base epitaxial layer 235, such as shown in FIG. 21 and FIG. 22. In FIG. 21, the superlattice layers 238 and 240 are substantially flat. In FIG. 22, formation conditions are adjusted so that the superlattice layers 238 and 240 have curvature shapes. In various embodiments, the superlattice 236 fully covers the substrate 202 in the source/drain trenches 228 and yet stays below the bottom surface of the bottommost channel layer 208 such that the top surface of the superlattice 236 intersects the sidewall of the bottommost inner spacer feature 234.

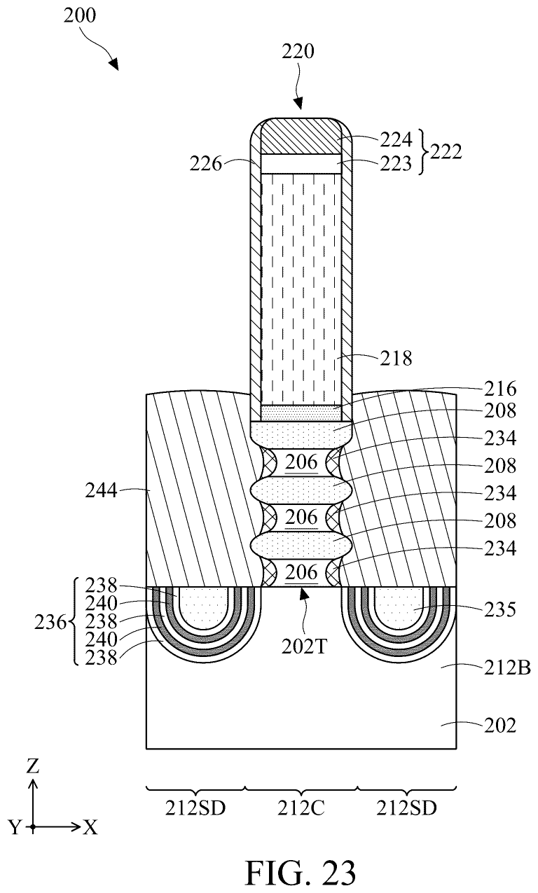

In another alternative embodiment, formation conditions are adjusted so that the superlattice layers 238 and 240 conformally cover the exposed top surface of the substrate 202, as shown in FIG. 23. Method 100 may optionally form the base epitaxial layer 235 in the remaining space surrounded by the superlattice layers 238 and 240. The superlattice 236 and the base epitaxial layer 235 collectively separate the source/drain feature 244 from contacting the substrate 202.

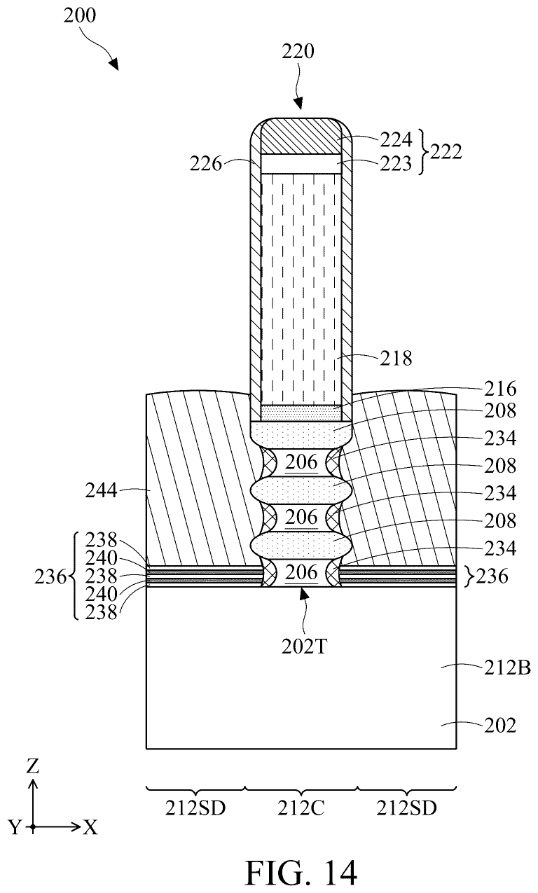

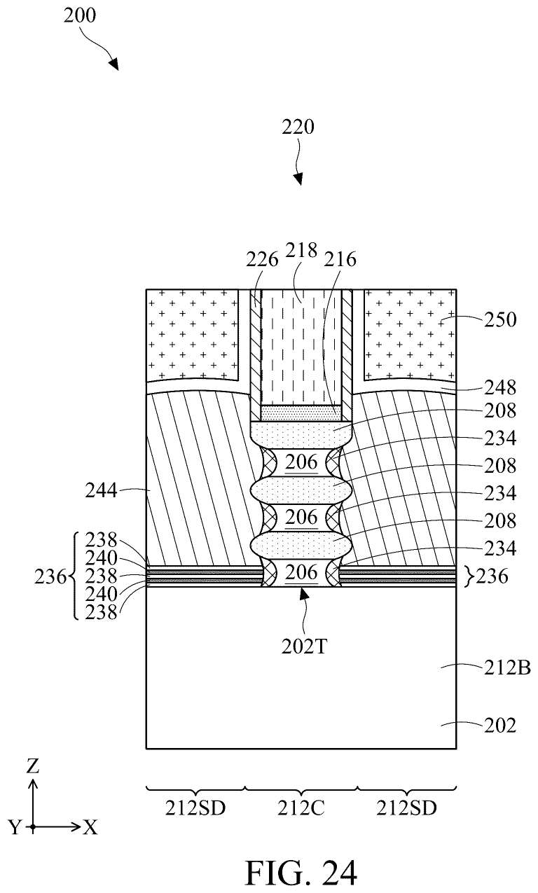

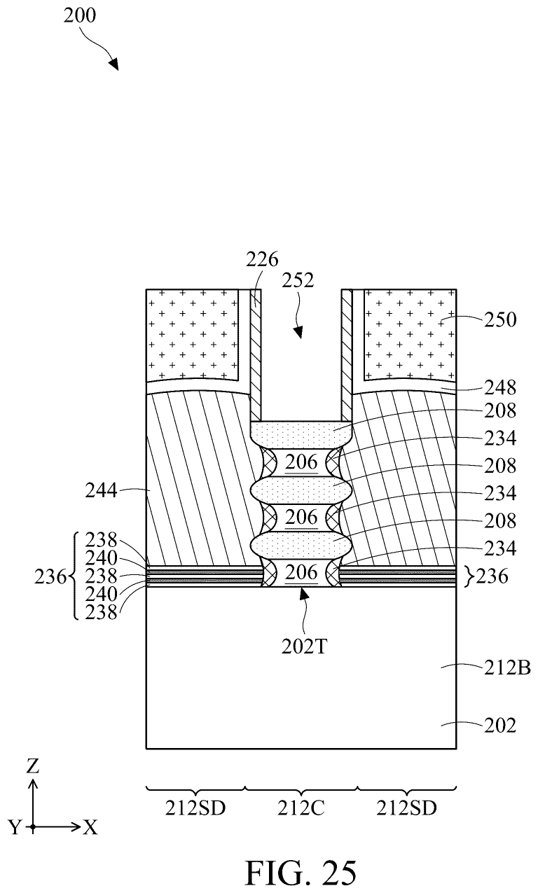

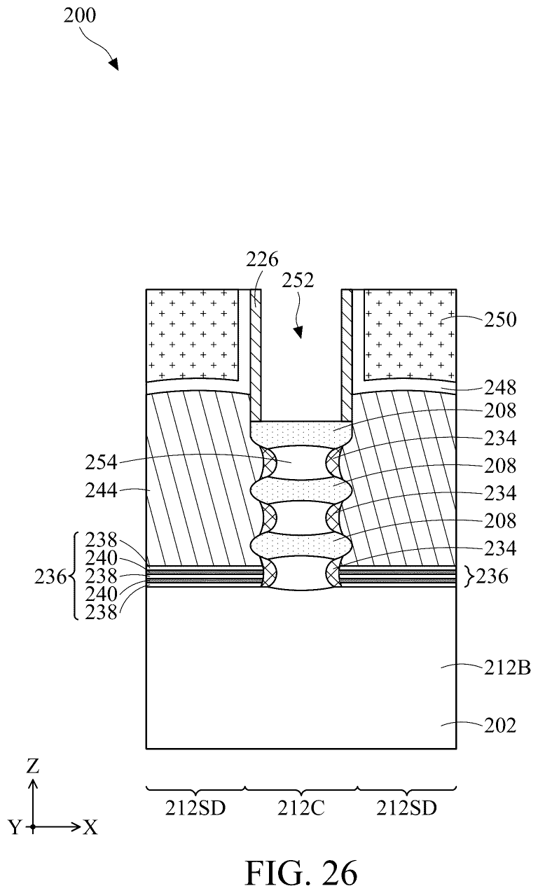

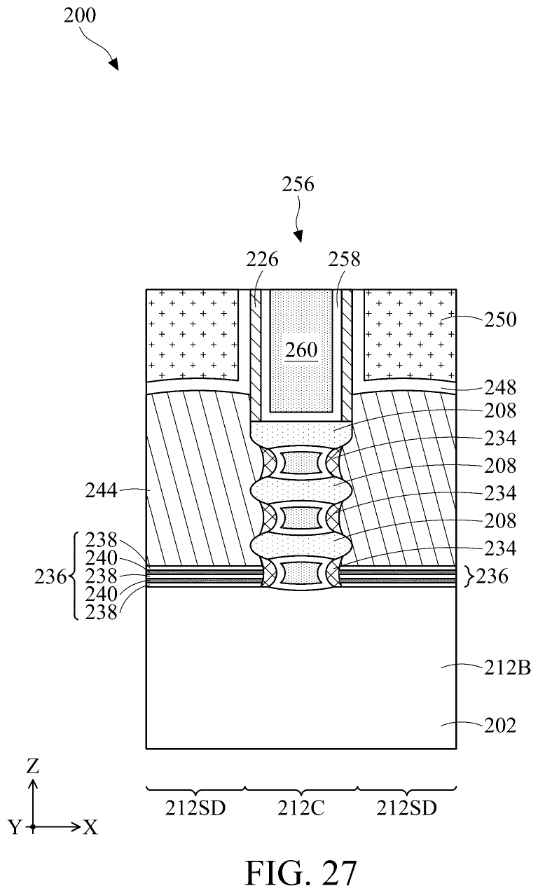

Referring to FIGS. 1 and 24-27, method 100 includes a block 122 where further processes are performed. To avoid unnecessary duplication, in FIGS. 24-27 the manufacturing operations after the structure shown in FIG. 14 is formed are explained. It is understood that those alternative configurations depicted in FIGS. 15 and 18-23 are equally applicable during further processes at block 122. Such further processes may include, for example, deposition of a contact etch stop layer (CESL) 248 over the workpiece 200 (shown in FIG. 24), deposition of an interlayer dielectric (ILD) layer 250 over the CESL 248 (shown in FIG. 24), removal of the dummy gate stack 220 (shown in FIG. 25), selective removal of the sacrificial layers 206 in the channel region 212C to release the channel layers 208 as channel members (shown in FIG. 26), and formation of a gate structure 256 over the channel region 212C (shown in FIG. 27).

Referring now to FIG. 24, the CESL 248 is formed prior to forming the ILD layer 250. In some examples, the CESL 248 includes silicon nitride, silicon oxynitride, and/or other materials known in the art. The CESL 248 may be formed by ALD, plasma-enhanced chemical vapor deposition (PECVD) process and/or other suitable deposition processes. The ILD layer 250 is then deposited over the CESL 248. In some embodiments, the ILD layer 250 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 250 may be deposited by a PECVD process or other suitable deposition technique. In some embodiments, after formation of the ILD layer 250, the workpiece 200 may be annealed to improve integrity of the ILD layer 250. As shown in FIG. 24, the CESL 248 is disposed directly on top surfaces of the source/drain feature 244.

Referring to FIGS. 24 and 25, after the deposition of the CESL 248 and the ILD layer 250, the workpiece 200 may be planarized by a planarization process to expose the dummy gate stack 220. For example, the planarization process may include a chemical mechanical planarization (CMP) process. After the CMP process, a distance from the top surface of the dummy gate stack 220 to the top surface of the topmost channel layer 208 may measure between 5 nm and about 50 nm along the Z direction. Exposure of the dummy gate stack 220 allows the removal of the dummy gate stack 220 and release of the channel layers 208. In some embodiments, the removal of the dummy gate stack 220 results in a gate trench 252 over the channel regions 212C. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220. After the removal of the dummy gate stack 220, sidewalls of the channel layers 208 and the sacrificial layers 206 in the channel region 212C are exposed in the gate trench 252.

Referring to FIG. 26, after the removal of the dummy gate stack 220, the method 100 may include operations to selectively remove the sacrificial layers 206 between the channel layers 208 in the channel region 212C. The selective removal of the sacrificial layers 206 releases the channel layers 208 to form channel members (also numbered as 208). The selective removal of the sacrificial layers 206 also leaves behind space 254 between channel members 208. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

Referring to FIG. 27, the method 100 may include further operations to form the gate structure 256 to wrap around each of the channel members 208. In some embodiments, the gate structure 256 is formed within the gate trench 252 and into the space 254 left behind by the removal of the sacrificial layers 206. In this regard, the gate structure 256 wraps around each of the channel members 208. The gate structure 256 includes a gate dielectric layer 258 and a gate electrode layer 260 over the gate dielectric layer 258. In some embodiments, while not explicitly shown in the figures, the gate dielectric layer 258 includes an interfacial layer and a high-K gate dielectric layer. High-K dielectric materials, as used and described herein, include dielectric materials having a high dielectric constant, for example, greater than that of thermal silicon oxide (˜3.9). The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-K gate dielectric layer may include hafnium oxide. Alternatively, the high-K gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr) TiO₃ (BST), silicon nitride (SiN), silicon oxynitride (SiON), combinations thereof, or other suitable material. The high-K gate dielectric layer may be formed by ALD, physical vapor deposition (PVD), CVD, oxidation, and/or other suitable methods.

The gate electrode layer 260 of the gate structure 256 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 260 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 260 may be formed by ALD, PVD, CVD, e-beam evaporation, or other suitable process. In various embodiments, a CMP process may be performed to remove excessive metal, thereby providing a substantially planar top surface of the gate structure 256. The gate structure 256 includes portions that interpose between channel members 208 in the channel region 212C.

Still referring to FIG. 27, upon conclusion of the operations at block 122, a transistor 280 (particularly a p-type transistor; also can be either an n-type transistor or a p-type transistor) is substantially formed. The transistor 280 includes channel members 208 that are vertically stacked along the Z direction. Each of the channel members 208 is wrapped around by the gate structure 256. The channel members 208 extend or are sandwiched between two source/drain features 244 along the X direction. Underneath the source/drain features 244 are the superlattice 236. The superlattice 236 (optionally with the base epitaxial layer 235) exhibit high resistivity due to the non-semiconductor layers 240, thus providing a high resistance path from the source/drain features 244 to the substrate 202, such that the leakage current into the substrate 202 is suppressed. The superlattice structure in the superlattice 236 allows the crystalline structures from the substrate 202 to extend and thus allows the source/drain features 244 to also grow from the top surface of the superlattice 236, such that the compressive strain provided to the channel members 208 is not compromised.

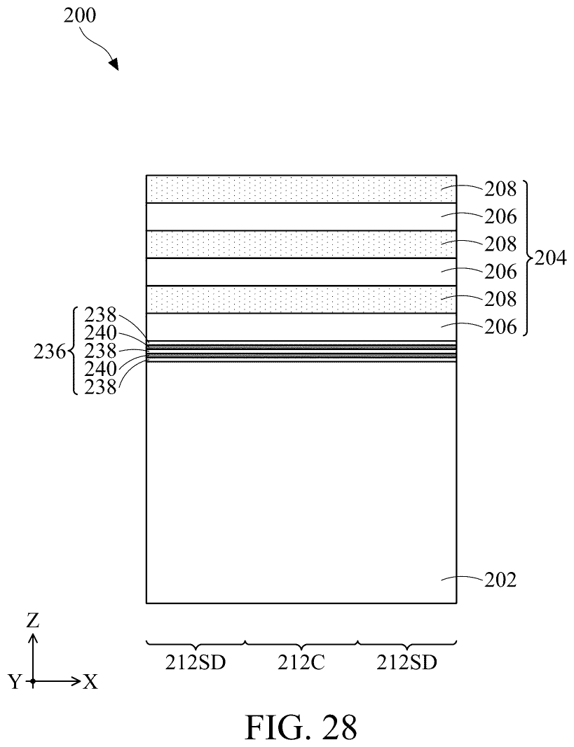

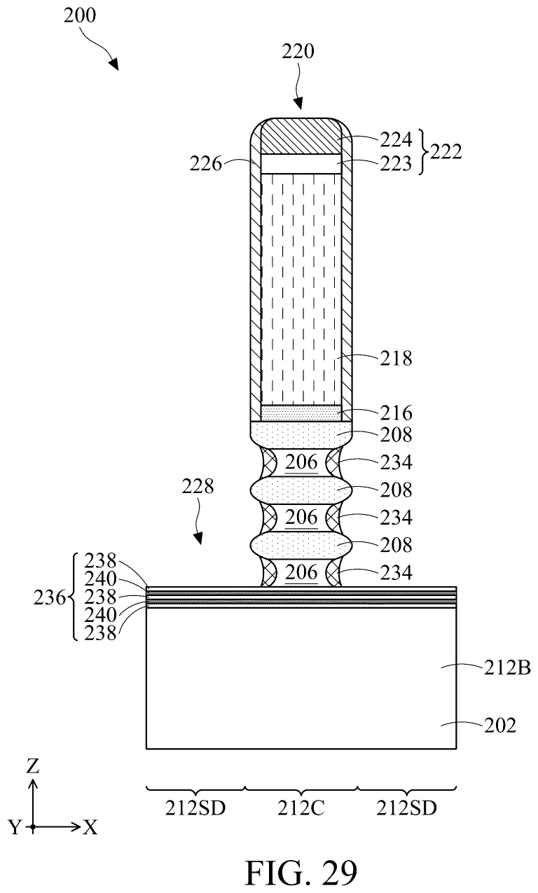

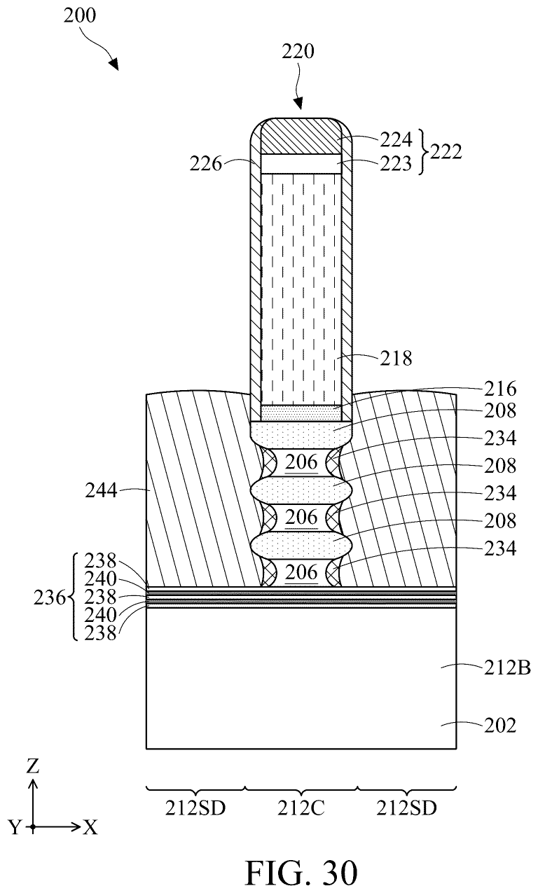

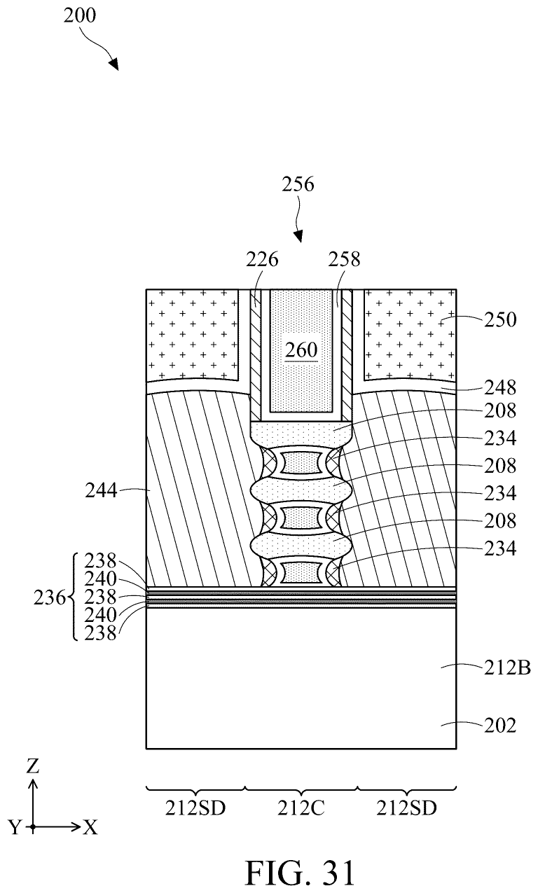

Referring to FIGS. 28-31, in some alternative embodiments, method 100 may form the superlattice 236 prior to the formation of the stack 204. The superlattice structure of the superlattice 236 preserves the crystalline orientation of the substrate 202 and allows the layers in the stack 204 to epitaxially grow from the top layer of the superlattice 236, as shown in FIG. 28. The superlattice 236 may also function as an etch stop layer during the formation of the source/drain trenches 228 and the formation of the inner spacer features 234, as shown in FIG. 29. The superlattice 236 allows the source/drain features 244 to epitaxially grow from the top layer of the superlattice 236, as shown in FIG. 30. During the gate replacement process, the superlattice 236 may also function as an etch stop layer during the formation of the gate trench 252 and the release of the channel members 208. After the gate structure 256 is formed, the top layer of the superlattice 236 is in direction contact with the gate dielectric layer 258, as well as the bottommost inner spacer features 234 and the source/drain features 244, as shown in FIG. 31.

Although not intended to be limiting, one or more embodiments of the present disclosure provide many benefits to a semiconductor device and the formation thereof. For example, embodiments of the present disclosure provide a transistor that includes a vertical stack of the channel members extending between two source/drain features and a superlattice interposing the source/drain features and the substrate. The source/drain features are spaced apart from the substrate by the superlattice and optionally an undoped base epitaxial layer. The superlattice suppresses substrate current leakage but also allows the source/drain features to directly grow from the bottom of the source/drain trenches. By allowing the source/drain features to directly grow from the bottom of the source/drain trenches besides from sidewalls of the channel layers, the source/drain features maintains a suitable amount of strain to the channel region.

In one exemplary aspect, the present disclosure is directed to a method. The method includes forming a stack over a substrate, the stack comprising a plurality of channel layers interleaved by a plurality of sacrificial layers, patterning the stack to form a fin-shape structure, the fin-shape structure comprising a channel region and a source/drain region, forming a dummy gate stack over the channel region of the fin-shape structure, depositing a gate spacer layer over the dummy gate stack, recessing the source/drain region to form a source/drain trench that exposes a top surface of the substrate, sidewalls of the channel layers, and sidewalls of the sacrificial layers, depositing a superlattice in the source/drain trench, the superlattice including at least one dielectric layer sandwiched between two semiconductor layers, epitaxially growing a source/drain feature from the superlattice and the sidewalls of the channel layers, removing the dummy gate stack, releasing the channel layers in the channel region, and forming a metal gate structure wrapping around each of the channel layers. In some embodiments, the depositing of the superlattice includes an epitaxial growing process. In some embodiments, each layer in the superlattice maintains a same crystalline orientation as the top surface of the substrate. In some embodiments, the two semiconductor layers of the superlattice are crystalline silicon layers. In some embodiments, the dielectric layer of the superlattice includes oxygen doped silicon or nitrogen doped silicon. In some embodiments, the dielectric layer is a monolayer. In some embodiments, the method further includes laterally recessing the sidewalls of the sacrificial layers to form a plurality of inner spacer recesses, and forming a plurality of inner spacer features in the inner spacer recesses. A top surface of the superlattice intersects a sidewall of a bottommost one of the inner spacer features. In some embodiments, the method further includes prior to the depositing of the superlattice, forming an undoped epitaxial layer in the source/drain trench. The superlattice is in contact with a top surface of the undoped epitaxial layer. In some embodiments, the method further includes after the depositing of the superlattice, forming an undoped epitaxial layer in the source/drain trench, wherein the superlattice is in contact with a bottom surface of the undoped epitaxial layer.

In another exemplary aspect, the present disclosure is directed to a method. The method includes forming a first stack over a substrate, the first stack comprising a plurality of semiconductor layers interleaved by a plurality of dielectric layers, forming a second stack over the first stack, the second stack comprising a plurality of channel layers interleaved by a plurality of sacrificial layers, patterning the second stack to form a fin-shape structure, recessing a portion of the fin-shape structure to form a recess exposing a top surface of the first stack, epitaxially growing an epitaxial feature directly from the top surface of the first stack, removing the sacrificial layers to release the channel layers, and forming a gate structure wrapping around each of the channel layers. In some embodiments, the gate structure is in contact with the first stack. In some embodiments, each of the dielectric layers includes one or more monolayers of silicon dioxide or silicon nitride. In some embodiments, each of the semiconductor layers includes crystalline silicon. In some embodiments, the method further includes laterally recessing the sacrificial layers to form a plurality of cavities, and forming a plurality of dielectric features in the cavities. The top surface of the first stack is in direct contact with a bottommost one of the dielectric features. In some embodiments, a thickness of the first stack ranges from about 2 nm to about 10 nm.

In yet another exemplary aspect, the present disclosure is directed to a semiconductor device. The semiconductor device includes a plurality of nanostructures vertically stacked above a substrate, a gate structure wrapping around each of the nanostructures, a source/drain feature abutting the nanostructures, and a superlattice interposing the substrate and a bottom surface of the source/drain feature. The superlattice includes at least one dielectric layer sandwiched between two semiconductor layers. In some embodiments, the substrate includes a crystalline structure, and the dielectric layer and the semiconductor layers of the superlattice maintain a same crystalline orientation as the substrate. In some embodiments, the dielectric layer includes one or more monolayers of oxygen doped silicon or nitrogen doped silicon, and the semiconductor layers each include crystalline silicon. In some embodiments, the superlattice extends to a position directly under the gate structure. In some embodiments, the semiconductor device further includes an undoped epitaxial layer under the source/drain feature. The undoped epitaxial layer is in contact with the superlattice.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a stack over a substrate, the stack comprising a plurality of channel layers interleaved by a plurality of sacrificial layers;
patterning the stack to form a fin-shape structure, the fin-shape structure comprising a channel region and a source/drain region;
forming a dummy gate stack over the channel region of the fin-shape structure;
depositing a gate spacer layer over the dummy gate stack;
recessing the source/drain region to form a source/drain trench that exposes a top surface of the substrate, sidewalls of the channel layers, and sidewalls of the sacrificial layers;
depositing a superlattice in the source/drain trench, the superlattice including at least one dielectric layer sandwiched between two semiconductor layers;
epitaxially growing a source/drain feature from the superlattice and the sidewalls of the channel layers;
removing the dummy gate stack;
releasing the channel layers in the channel region; and
forming a metal gate structure wrapping around each of the channel layers.

2. The method of claim 1, wherein the depositing of the superlattice includes an epitaxial growing process.

3. The method of claim 1, wherein each layer in the superlattice maintains a same crystalline orientation as the top surface of the substrate.

4. The method of claim 1, wherein the two semiconductor layers of the superlattice are crystalline silicon layers.

5. The method of claim 1, wherein the dielectric layer of the superlattice includes oxygen doped silicon or nitrogen doped silicon.

6. The method of claim 1, wherein the dielectric layer is a monolayer.

7. The method of claim 1, further comprising:
laterally recessing the sidewalls of the sacrificial layers to form a plurality of inner spacer recesses; and
forming a plurality of inner spacer features in the inner spacer recesses,
wherein a top surface of the superlattice intersects a sidewall of a bottommost one of the inner spacer features.

8. The method of claim 1, further comprising:
prior to the depositing of the superlattice, forming an undoped epitaxial layer in the source/drain trench, wherein the superlattice is in contact with a top surface of the undoped epitaxial layer.

9. The method of claim 1, further comprising:
after the depositing of the superlattice, forming an undoped epitaxial layer in the source/drain trench, wherein the superlattice is in contact with a bottom surface of the undoped epitaxial layer.

10. A method, comprising:
forming a first stack over a substrate, the first stack comprising a plurality of semiconductor layers interleaved by a plurality of dielectric layers;
forming a second stack over the first stack, the second stack comprising a plurality of channel layers interleaved by a plurality of sacrificial layers;
patterning the second stack to form a fin-shape structure;
recessing a portion of the fin-shape structure to form a recess exposing a top surface of the first stack;
epitaxially growing an epitaxial feature directly from the top surface of the first stack;
removing the sacrificial layers to release the channel layers; and
forming a gate structure wrapping around each of the channel layers.

11. The method of claim 10, wherein the gate structure is in contact with the first stack.

12. The method of claim 10, wherein each of the dielectric layers includes one or more monolayers of silicon dioxide or silicon nitride.

13. The method of claim 10, wherein each of the semiconductor layers includes crystalline silicon.

14. The method of claim 10, further comprising:
laterally recessing the sacrificial layers to form a plurality of cavities; and
forming a plurality of dielectric features in the cavities,
wherein the top surface of the first stack is in direct contact with a bottommost one of the dielectric features.

15. The method of claim 10, wherein a thickness of the first stack ranges from about 2 nm to about 10 nm.

16. A semiconductor device, comprising:
a plurality of nanostructures vertically stacked above a substrate;
a gate structure wrapping around each of the nanostructures;
a source/drain feature abutting the nanostructures; and
a superlattice interposing the substrate and a bottom surface of the source/drain feature, wherein the superlattice includes at least one dielectric layer sandwiched between two semiconductor layers.

17. The semiconductor device of claim 16, wherein the substrate includes a crystalline structure, and the dielectric layer and the semiconductor layers of the superlattice maintain a same crystalline orientation as the substrate.

18. The semiconductor device of claim 16, wherein the dielectric layer includes one or more monolayers of oxygen doped silicon or nitrogen doped silicon, and the semiconductor layers each include crystalline silicon.

19. The semiconductor device of claim 16, wherein the superlattice extends to a position directly under the gate structure.

20. The semiconductor device of claim 16, further comprising:
an undoped epitaxial layer under the source/drain feature, wherein the undoped epitaxial layer is in contact with the superlattice.
